(19) United States
(12) Patent Application Publication
(10) Pub. No.: US 2014/0233093 A1
(43) Pub. Date: Aug. 21, 2014

(54) MULTILAYER SYSTEMS FOR SELECTIVE REFLECTION OF ELECTROMAGNETIC RADIATION FROM THE WAVELENGTH SPECTRUM OF SUNLIGHT AND METHOD OF PRODUCING SAME

(71) Applicant: Southwall Europe GmbH, Grossroenhrsdorf (DE)

(72) Inventors: Roland Claus Thielsch, Dresden (DE); Ronny Kleinhempel, Gelenau (DE); Andre Karl-Heinz Wahl, Grossroehrdorf (DE)

(73) Assignee: SOUTHWALL EUROPE GMBH, Grossroehrsdorf (DE)

(21) Appl. No.: 14/347,435

(22) PCT Filed: Sep. 28, 2012
(86) PCT No.: PCT/EP2012/069204

§ 371 Date: Mar. 26, 2014

(30) Foreign Application Priority Data
Oct. 13, 2011 (DE) 10 2011 116 191.4

(51) Int. Cl. G02B 5/26; C23C 14/14; C23C 14/35

(52) U.S. Cl. CPC G02B 5/26; C23C 14/35; C23C 14/14
USPC 359/360; 359/359; 204/192.27

(57) ABSTRACT

The invention relates to multilayer systems for selective reflection of electromagnetic radiation from the wavelength spectrum of sunlight, and to a method for producing said systems on suitable, preferably polymeric, carrier materials. Such a multilayer system of the invention is formed with at least one layer composed of silver or silver alloy, which is coated over the whole area on both surfaces with in each case a seed layer and a cap layer. In this case, the seed layer and cap layer are formed from dielectric material. These are ZnO and/or ZnO:X. In this case, at least one such multilayer system is formed on a flexible polymeric substrate, preferable a film which is optically transparent in the visible spectral range.

The invention relates to multilayer systems for selective reflection of electromagnetic radiation from the wavelength spectrum of sunlight, and to a process for producing said systems on suitable, preferably polymeric, carrier materials.

The preferred but not exclusive usage of such a composite material consisting of these multilayer systems with this carrier is the production of laminated composite glazing in conjunction with other polymeric adhesive films and glass.

Another usage is a combination of this laminated material with other coated or uncoated films and adhesives for use as “window film” for subsequent application on glazing.

Such multilayer systems are used for a targeted, selective influencing of the transmission and reflection of electromagnetic radiation emitted by the sun, and are formed as thin layers on substrates that are transparent to electromagnetic radiation, such as in particular glass or polymeric films, by known vacuum coating processes, in particular PVD processes. An associated goal is to reflect the greatest possible amount of the radiation in the non-visible range (e.g., solar energy range or near infrared spectral range) so that the amount of transmitted solar energy is minimized. A special goal is to limit the value of the total solar transmission T_{TS} (calculated according to DIN ISO 13837, case 1) transmitted through a composite glazing provided with such a multilayer system on this carrier to a maximum of 40% of the electromagnetic radiation emitted by the sun and striking the surface of the earth. As a result, the heating inside of rooms or vehicles would be minimized and the energy needed for creating a comfortable ambient climate for a person inside would be reduced. In contrast to the above, however, a greatest possible amount of the radiation in the range of visible light should not be reflected, and to the extent possible also not be absorbed, so that the percentage of the solar radiation visible to the human eye (Tᵥᵢₛ, calculated according to ASTM E 308 for illumination source A and observer 2°) can be kept above 70%. This requirement for Tᵥᵢₛ is prescribed by law for the use in vehicle glazing.

For this purpose, multilayer systems that are formed on substrates (glass or plastic) have long been used. These may be alternating layer systems in which layers of dielectric material with a high and low refractions are formed on each other.

Thin metallic layers are also used frequently, alternating with thin dielectric layers (oxides and nitrides). These oxides or nitrides should feature optical refractive indices with a wavelength of 550 nm in the range of 1.8 to 2.5.

In addition to other reflecting metals such as gold or copper, preferably silver or silver alloys (Ag—Au, Ag—Cu, Ag—Pd and others) are used for the metallic layers, which have very good optical qualities for these applications.

It is thereby advantageous to deposit such a silver or silver alloy layer onto a seed layer.

In order to apply a complex multilayer system consisting of a series of oxide layers and Ag layers, it is customary that an Ag layer that has already been applied/deposited is coated over with oxides in a reactive sputtering process.

As is known, Ag readily oxidizes in the presence of oxidizing media such as O₂ or H₂O, but especially in a reactive plasma that contains these gases. The oxidation is accompanied by a distinct deterioration of the qualities of the Ag, so that as a rule the desired visual and energetic qualities of such a multilayer system are not achieved without special countermeasures. One protective measure in accordance with the prior art is the application of a very thin metallic layer onto the silver layer.

At present, Ti or NiCr alloys with a typical layer thickness <5 nm are typically used as cap layers. This should avoid the oxidation of the silver on the layer surface since the direct contact of the surface with the oxygen as well as with other reactive constituents of the atmosphere (plasma) can be avoided in the subsequent formation of a dielectric layer. The silver is protected in this form from degradation, whereby the metallic cap layer may oxidize.

Since a separate coating station is needed in the coating machine for the deposition of the thin cap layer, it cannot be used for the depositing of dielectric material (which is needed for the optical effect of the layer system). This generally results in a longer coating time and therefore elevated coating costs.

In multilayer systems, the boundary surface roughness generally increases as the number of layers increases. In the case of thin silver layers, this may imply that the second and third silver layer in a multilayer system feature poorer electrical and optical qualities at a comparable thickness. This can be indirectly demonstrated, e.g., by measuring the electrical resistance. In addition, the transparency for electromagnetic radiation in the wavelength of visible light is reduced by additional absorption effects on the rough boundary surface between silver and dielectric layers.

The invention therefore has the task of providing a multilayer system for the application cases “glass laminate” for vehicle glazing and “window film” that has improved qualities.

These are a high transmission and low reflection in the visible spectral range on the one hand, and a low transmission and a high reflection of radiation components from the non-visible spectral range (near infrared range) on the other hand.

At the same time another task of the invention is to provide for a process for depositing onto a suitable carrier that is suitable for the industrial production of this multilayer system. In particular, this invention has the task of providing a process for an economical application onto a polymeric carrier material that can be used in the roll-to-roll process.

According to the invention this task is solved with multilayer systems comprising the features of claim 1. A production process for these multilayer systems is defined with claim 8. Advantageous embodiments and further developments can be realized with features designated in subordinate claims.

A multilayer system according to the invention for a selective reflection of electromagnetic radiation from the wavelength spectrum of sunlight is formed with at least one layer of silver or of a silver alloy, that is entirely coated with a seed layer and a cap layer on both surfaces, whereby the seed layer and cap layer are formed from a dielectric material. The seed layer and also the cap layer are formed from ZnO and/or ZnO:X. At least one such multilayer system is formed on a flexible polymeric substrate, preferably a film that is optically transparent in the visible spectral range. A seed layer and a cap layer can be formed from the pure ZnO or from the doped zinc oxide. Alternatively, one of the two layers can be formed from the ZnO and the other layer from the doped ZnO. In addition to pure silver, a silver alloy in which small amounts of Au, Pd or Cu can also be used. In the following the layers are generally referred to as silver layer. In silver alloys the amount of other metal contained should be very small, if possible less than 2%.

Such a multilayer system or several of these multilayer systems can be formed superposed over each other on the substrate. Traditional vacuum coating processes, in particular PVD processes and especially advantageously magnetron sputtering can be used for these purposes.

The coating on plastic substrates (polymer films) is frequently carried out in a batch operation since these substrates are generally available in roll form with a finite length.

For these purposes, it is advantageous if the seed layer as well the cap layer can be sputtered from the same target material. That is, the same material fulfills the corresponding function in principle. It is thereby possible to adapt in each coating step the particular gas mixture supplied into the coating area for the seed layer on the one hand, and for the cap layer on the other hand, in order to optimize the particular function in this manner. This allows a particularly economical forward and backward coating by winding back and forth (a system with seed layer—silver—cap layer is deposited at each winding around). The multilayer system can be produced without time-consuming aeration procedures for suspending the roll even with multiple silver layers as well as seed layers and cap layers. The targets for the formation of the seed layer, the silver layer and the cap layer are successively arranged in the direction of the substrate feed axis. The targets for the formation of the seed layer and the cap layer can be formed from the same material.

If, during coating, the substrate is wound from roll to roll, a seed layer, or, alternatingly, in case of an opposite feed direction, a cap layer can be formed, depending on the substrate's feed direction, with respective targets. As a result, in particular in multilayer systems with multiple silver layers that are enclosed by a seed layer and a cap layer, the time and the expense for the production can be reduced.

For these purposes it is not absolutely necessary that several multilayer systems according to the invention are deposited by back-and-forth winding. Another possibility is that after each coating step (for depositing a multilayer system), the coated roll is removed, the roll is loaded on the original winding-off station and is coated just as in coating step 1.

Mixed oxides ZnO:X with X e.g., Al₂O₃, Ga₂O₃, SnO₂, In₂O₃or MgO may be used for forming the seed layer and the cap layer. For these purposes, corresponding targets with the respective composition, that is, pure ZnO or at least one other of the cited oxides, may be used for coating. The percentage of these oxides that is contained in the seed layer and cap layer in addition to the ZnO should not exceed 20% by weight, and a percentage of 10% by weight is to be preferred, especially in order to ensure the shaping of the crystalline structure for the seed layer.

The seed layer and/or the cap layer should feature a layer thickness in the range of 5 nm to 15 nm, and the silver layer should feature a layer thickness between 5 nm and 25 nm, preferably 10 nm.

There is the advantageous possibility of forming additional dielectric layers that enclose such a multilayer system on both sides.

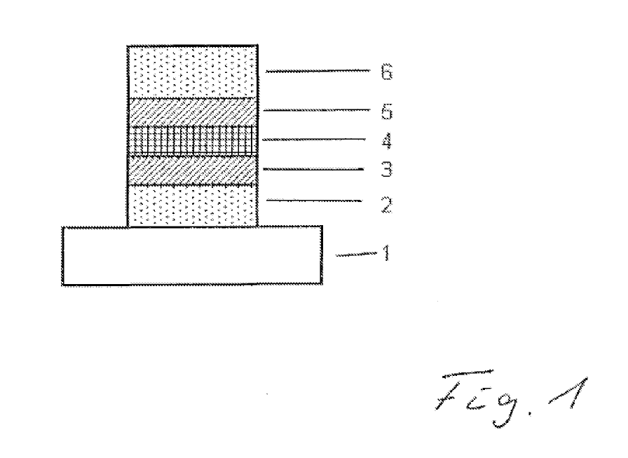

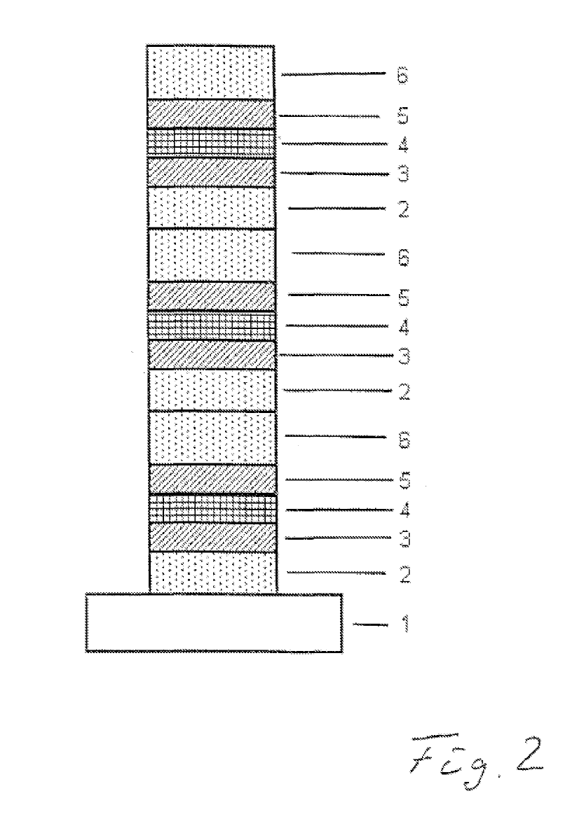

In order to realize a multiple silver layer system according to the invention, two or more mono-silver layer systems, preferably three mono-silver layer systems, are to be deposited onto a substrate in accordance with FIG. 2 in a sequence of coating steps. A mono-silver layer system is a construction of a dielectric layer, a thin seed layer, a silver layer, a cap layer and a closing dielectric layer (see FIG. 1).

In order to achieve the desired optical qualities, the thicknesses of the silver layers and the thicknesses of the dielectric layers should be adapted. The dielectric layers have a refractive index of n>1.8 at a wavelength of 550 nm, as well as a lower absorption and can preferably be formed from In₂O₃.

A dielectric layer construction formed between two silver layers consisting of a cap layer, a dielectric layer and a seed layer has the effect of a dielectric spacer layer in an optical filter system for defining the position of the spectral transmission range and the color impression of a composite glass as known from prior art. The invention has the particular advantage that the thicknesses of the seed and cap layers contribute to the layer thickness of dielectric spacer layers since they bring about an optical effect corresponding to that of other dielectric materials and contribute to the optical effect as a whole. The contribution of the seed and cap layers to the dielectric thickness in the layer system can be taken into account with their optical refractive index and geometric thickness in the construction of the multilayer system. The optical refractive index of ZnO at a wavelength of 550 nm is approximately 1.95-2.05, depending on the depositing conditions. It may slightly deviate from this by the percentage of additional oxide contained in a seed and/or cap layer. Adaptation to the desired optical effect in cooperation with other dielectric layers consisting of other materials is therefore possible.

In the formation of multilayer systems, three targets can be used with vacuum coating for the formation of the silver layer and of the seed and cap layers, which targets are serially arranged in the feed axis direction during coating, and/or may be used. In particular when coating from roll to roll as it is done in film substrate coating batch operations, this has the advantage that in a formation of a layer construction in which several multilayer systems according to the invention are to be formed above each other, the equipment and the time involved can be reduced. Thus, independently of the direction of movement of the substrate, at first a seed layer with a ceramic target ZnO and/or ZnO:X can be formed, followed by the silver layer with a silver target and the cap layer with a second ZnO and/or ZnO:X target. The conditions of the process, and in this case, the composition of the gas supplied into the coating area for seed/cap layer in particular, can be kept constant or identical in each coating step.

During the formation of the seed and cap layers, the gas mixture (sputtering gas) used should consist of argon, oxygen and hydrogen, and feature a composition suitable for the seed layer and the cap layer. The percentage of oxygen and hydrogen in the sputtering gas should be in a certain range (orientation value is <10%, but may deviate as a result of respective coating equipment such as gas inlet and pump arrangement) in order to achieve the desired layer structure for an optimal seed effect that positively influences the layer growth of the subsequently applied silver layer on the one hand, and to deposit optically transparent (absorption-free) layers on the other hand. Coating can take place at a typical pressure within the coating range of 0.4-1.0 Pa.

A suitable gas composition should also be selected for the cap layer on the silver, in order to ensure a sufficiently protective effect. Here, the oxygen concentration should be kept low (orientation value is <10% of the total amount of gas). For these purposes, it is additionally advantageous to select a hydrogen percentage higher than the oxygen percentage (orientation value is <15% of the total amount of gas).

Through use according to the invention of seed and cap layers of ZnO and/or ZnO:X, the quality of the silver layers can be improved. This can be explained by an improved growth of silver on the one hand, and by the corresponding protective action of the cap layer on the other hand. Another positive influence can be seen in the formation of very smooth boundary layers between the seed layer and the following silver layer, and between the deposited silver layer and the cap layer applied onto it.

It is known that due to structural properties conditioned by growth, thin silver layers have qualities that significantly differ from those of the solid material and that limit the achievable qualities of the layer systems.

The application of a thin, growth-influencing layer known in English as a “seed layer” should ensure that better qualities that are more similar to those of solid Ag are achieved by a regular growth (layer formation) that begins already at a low layer thickness. This succeeds especially well in the case of the invention, since the seed layers consisting of ZnO and/or ZnO:X feature a crystalline structure whose structure has an epitactic relationship with the structure of silver.

In particular, it is important that the coating conditions allow that the seed layer a) grows in a primarily crystalline manner and b) at the same time has the specific crystalline direction of preference for the regular growth for the silver layer meant to grow on it.

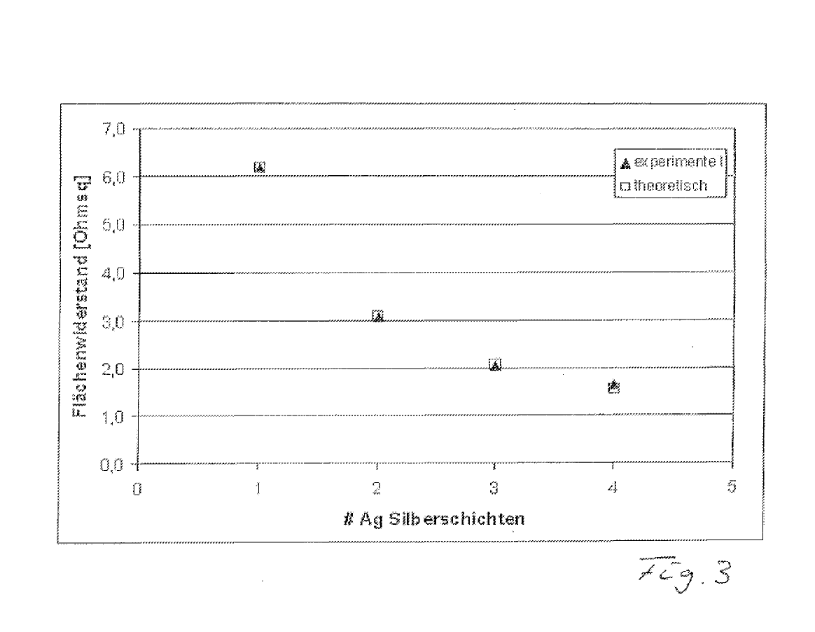

In multi-silver layer systems in which several multilayer systems are formed above each other it was also possible to demonstrate through surface resistance measurements that the electrical conductivity of the second, third and also of the fourth silver layer is comparable to that of the first one. In other words, it can therefore be shown that the layer quality of the silver layers, and therefore also the low roughness of the boundary layers, are realized in a layer stack consisting of several such layer sequences (see FIG. 3).

In highly efficient sun protection layers for automobile construction glazing, a desired total solar transmission of T_{TS}<40% and Tᵥᵢₛ>70% and Rᵥᵢₛ<10% could be achieved. However, layer systems that have a higher Rᵥᵢₛ value are also possible.

The layer thicknesses of the seed and cap layer(s) can also be selected for the targeted use of interfering with certain electromagnetic radiation. In multilayer systems with multiple silver layers, the seed and/or cap layers may also have different layer thicknesses, allowing them to interfere at different wavelengths.

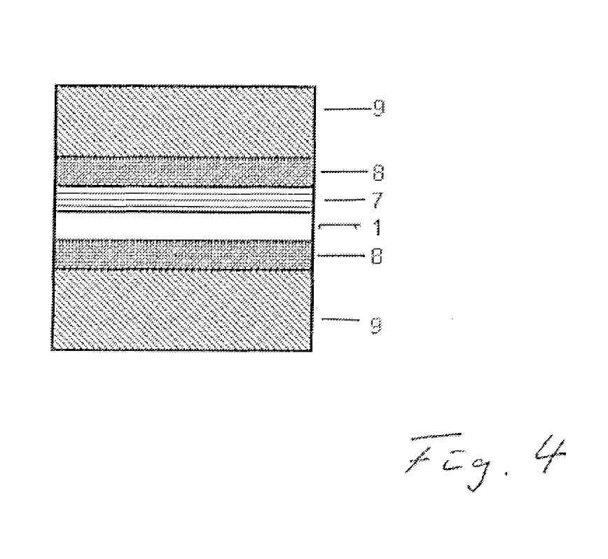

Thus, in a multilayer system construction according to the invention with three silver layers on a PET film as substrate, each surrounded by a seed and a cap layer as well as dielectric layers, and using a film coated accordingly in a glass laminate (FIG. 4), a total transmitted radiation percentage could be kept at T_{TS}<40%, the transmitted radiation percentage in the wavelength spectrum of visible light at Tᵥᵢₛ>70%, and the reflected radiation percentage in the wavelength spectrum of the visible light at Rᵥᵢₛ<10%.

The invention is explained in the following in an exemplary manner.

In the figures:

FIG. 1 schematically shows an example, in which a silver layer is enclosed by seed and cap layers;

FIG. 2 schematically shows an example, in which three silver layers are present, each with a seed and a cap layer in a multilayer system construction;

FIG. 3 shows a diagram with calculated and measured electrical surface resistances with a different number of silver layers in a multilayer system, and

FIG. 4 shows a schematic view for the inclusion of a multilayer system according to the invention with a plastic film embedded in a composite glass.

The example shown in FIG. 1 of a multilayer system with a silver layer 4 was applied in a coating step on the PET substrate 1. An In₂O₃ layer 2 with a layer thickness of 25 nm as dielectric layer was applied by magnetron sputtering in a reactive process using metallic indium targets. In the following coating station the seed layer 3 with a layer thickness of 8 nm was separated from a ceramic ZnO:X target doped with 2% Al₂O₃. Approx. 5% oxygen and hydrogen were mixed in with the sputtering gas argon. The deposit of the metallic silver layer 4 of 10 nm took place by magnetron atomization in an argon plasma. For the deposit of the cap layer 5 (layer thickness 7 nm), a ZnO:X target doped with 2% Al₂O₃was used as well. In this instance, 5% oxygen and 8% hydrogen were mixed in with the argon. The closing dielectric layer 6 of In₂O₃ with a layer thickness of 30 nm, in turn, was achieved by way of a reactive process using metallic indium targets.

With this mono-silver layer system, in one silver layer 4, a surface resistance of 6.2 Ohm□ was achieved.

The multilayer system construction shown in FIG. 2 with three silver layers 4 that were formed between a seed layer 3 and a cap layer 5, was achieved by way of three coating steps. In order to demonstrate the function of the seed layer 3 and cap layer 5, the multilayer system described for FIG. 1 was identically coated three times in succession.

However, for the realization of the required qualities regarding T_{TS}, Tᵥᵢₛ and Rᵥᵢₛ, the thicknesses of the In₂O₃ layers 2 and 6 and of the silver layers 4 had to be adapted. The seed layers 3 and cap layers 5 were produced under the same conditions in each coating step.

FIG. 2 shows a construction in which on a PET substrate 1, three multilayer systems according to the invention, each formed with a seed layer 3, a silver layer 4 and a cap layer 5, were formed. The layer thicknesses in the composition of the seed layers 3 and of the cap layers 5 correspond to the example in FIG. 1.

Thus, the dielectric layer 2 consisting of In₂O₃formed on the substrate 1 should have a layer thickness of 20 nm to 50 nm, the dielectric layers consisting of In₂O₃ that are formed between a seed layer 3 and a cap layer 5 should have a thickness in the range of 40 nm to 150 nm. The dielectric layer consisting of In₂O₃formed on the outer surface facing away from the substrate 1 should have a thickness in the range of 20 nm to 70 nm. All silver layers should have a layer thickness in the range of 7 nm to 25 nm.

By way of the experimentally determined electric surface resistance on a multilayer system with a silver layer and a layer thickness of 10 nm, the electrical surface resistance in a parallel circuit with additional 10 nm silver layers was estimated. The determined electrical resistances in the multilayer system constructions with multiple silver layers were compared with theoretically calculated values. FIG. 3 illustrates that the calculated values are congruent with the measured values for a two-, three- and four-silver layer system. This confirms that even the second, third and fourth silver layer can be produced in a multilayer system with comparably good silver qualities. This state of affairs results from the diagram shown in FIG. 3, and proves that there is no increase in the boundary surface roughness of the silver layers as the number of silver layers increases.

Furthermore, the multilayer system consisting of three multilayer systems according to the invention formed over each other may be optimized by adapting individual layer thicknesses in such a manner as to achieve the qualities T_{TS}<40%, Tᵥᵢₛ>70%, and Rᵥᵢₛ<10% in a glass laminate. The construction of the “glass laminate” is shown in FIG. 4. It comprises 1 a PET substrate, 7 a multilayer system according to the invention with three silver layers 4, 8 PVB (polyvinyl butyral) layers and 9 glass.

In the example shown in FIG. 4, the layer thicknesses for the seed layers 3 were left at 8 nm, and the cap layers 5 at 7 nm. The silver layers 4 had the following thicknesses (starting from the substrate 1): first silver layer=8.7 nm, second silver layer=16.9 nm, and third silver layer=13.7 nm. The dielectric layers 6 were produced from In₂O₃, and had the following thicknesses, again starting from substrate 1: 1st layer consisting of In₂O₃=24 nm, 2nd layer consisting of In₂O₃=76 nm, 3rd layer consisting of In₂O₃=90 nm and 4th layer consisting of In₂O₃=32 nm.

The following values were achieved with this layer system in the “glass laminate”:

### Tᵥᵢₛ (A, 2°)=72.4%

### Rᵥᵢₛ (A, 2°)=9.1%

T_{TS} (ISO)=38.1%.

1. A multilayer system for selective reflection of electromagnetic radiation from the wavelength spectrum of sunlight, comprising a flexible polymeric substrate, at least one a seed layer, at least one layer of silver or a silver alloy that is coated on the at least one seed layer, and at least one cap layer coated on the at least one seed layer, wherein the seed layer and cap layer are formed from a dielectric material comprising ZnO and/or a mixed zinc oxide, ZnO:X.

2. The multilayer system according to claim 1, wherein the mixed zinc oxide, ZnO:X, comprises up to 20% by weight of Al₂O₃, Ga₂O₃, SnO₂, In₂O₃, or a combination thereof.

3. The multilayer system according to claim 1, wherein the seed layer and/or the cap layer has a thickness of 5 nm to 15 nm and the silver layer has a thickness of 5 nm and 25 nm.

4. The multilayer system according to claim 1, further comprising a dielectric layer formed between the cap layer and a successive seed layer.

5. The multilayer system according to claim 1, wherein at least two multilayer systems are formed in a superposed manner.

6. The multilayer system according to claim 1, comprising a dielectric layer having a layer thickness in the range of 20 nm to 50 nm formed between the polymeric substrate and the multilayer system.

7. The multilayer system according to claim 5, further comprising a dielectric layer having a layer thickness of 40 nm to 150 nm between the multilayer systems, a dielectric layer having a layer thickness of 20 nm to 70 nm on the outer surface facing away from the substrate, or a combination thereof.

8. A process for the production of the multilayer system according to claim 1, comprising magnetron sputtering the at least one seed layer, the at least one silver layer, and the at least one cap layer, wherein targets for the formation of the at least one seed, silver, and cap layers are successively arranged in the feed axis direction of the substrate, and the targets for the formation of the at least one seed layer and at least one cap layer are formed from the same material.

9. The process according to claim 8, further comprising a gas composition used for the formation of the at least one seed layer and the at least one cap layer that is selected in coordination with the at least one seed layer and at least one cap layer formation.

10. The process according to claim 9, wherein a lesser percentage of oxygen and a greater percentage of hydrogen is maintained in the gas mixture for the formation of the at least one cap layer than in the formation of the at least one seed layer.

11. The process according to claim 8, wherein the flexible substrate is wound in opposite directions during the sputtering of the at least one seed layer and the sputtering of the at least one cap layer.

12. The multilayer system according to claim 4, wherein the dielectric layer comprises In₂O₃.
